(19) United States
(12) Patent Application Publication
(10) Pub. No.: US 2025/0089278 A1
(43) Pub. Date: Mar. 13, 2025

(54) HIGH-VOLTAGE CAPACITOR, MANUFACTURING METHOD THEREOF AND INTEGRATED DEVICE

(71) Applicant: Silergy Semiconductor Technology (Hangzhou) LTD., Hangzhou (CN)

(72) Inventors: Zheng LV, Hangzhou (CN); Chuan PENG, Hangzhou (CN); Xunyi SONG, Hangzhou (CN)

(73) Assignee: Silergy Semiconductor Technology (Hangzhou) LTD., Hangzhou (CN)

(21) Appl. No.: 18/830,617

(22) Filed: Sep. 11, 2024

(30) Foreign Application Priority Data
Sep. 11, 2023 (CN) 2023111814286

(51) Int. Cl. H01G 4/30

(52) U.S. Cl. CPC H10D 1/692

(57) ABSTRACT

A high-voltage capacitor and a manufacturing method thereof. The high-voltage capacitor includes a first electrode part, at least one interlayer dielectric layer disposed on the first electrode part, a groove disposed in a top surface of the interlayer dielectric layer, where projection of the groove in a vertical direction overlaps with the first electrode part, and a second electrode part of the high-voltage capacitor disposed on the top surface of the interlayer dielectric layer. The second electrode overlaps with the groove and extends beyond the sides of the groove. By providing the filled groove, the thickness of the dielectric layer at the edge of the lower surface of the second electrode part is increased compared to the capacitor's middle part, thereby improving the withstand voltage of the high-voltage capacitor.

### CROSS-REFERENCE TO RELATED APPLICATION

The present application claims the benefit of priority to Chinese Patent Application No. 202311181428.6, entitled “HIGH-VOLTAGE CAPACITOR, MANUFACTURING METHOD THEREOF AND INTEGRATED DEVICE”, filed with CNIPA on Sep. 11, 2023, the disclosure of which is incorporated herein by reference in its entirety for all purposes.

### FIELD OF THE INVENTION

The present disclosure relates to the field of semiconductor technology, specifically relates to a high-voltage capacitor, a manufacturing method for the high-voltage capacitor, and an integrated device.

### BACKGROUND OF THE INVENTION

High voltage capacitors can be integrated onto or packaged with functional semiconductor chips as capacitive isolators, which are applied to isolate different voltage domains, including automotive isolation devices that enable the safe transmission of electrical signals between different voltage domains.

### SUMMARY OF THE INVENTION

The present disclosure provides a high-voltage capacitor and a manufacturing method thereof.

One embodiment of the present disclosure relates to a method for manufacturing a high-voltage capacitor, including: forming a first electrode part of the high-voltage capacitor; forming at least one interlayer dielectric layer on the first electrode part; forming a groove in the top surface of the interlayer dielectric layer at a position corresponding to the first electrode part in a vertical direction, which extends from the upper surface of the top interlayer dielectric layer into its interior; and forming a second electrode part on the top surface of the interlayer dielectric layer, which covers the groove and a portion of the top surface of the interlayer dielectric layer which is connected to both sides of the groove. The at least one interlayer dielectric layer may include a stack of different interlayer dielectric layers.

Furthermore, the width of the groove is smaller than the width of the second electrode part in a transverse direction, which is perpendicular to the vertical direction.

Furthermore, the depth of the groove ranges from 1 um to 3 um.

Furthermore, before forming the second electrode part of the high-voltage capacitor, the method further includes: forming a first voltage-resistant dielectric layer on the top surface of the interlayer dielectric layer that includes the groove. The second electrode part is located on the upper surface of the first voltage-resistant dielectric layer.

Furthermore, the method further includes forming a second voltage-resistant dielectric layer on the second electrode part and the top surface of the interlayer dielectric layer, wherein the top surface of the interlayer dielectric layer covers at least the side surfaces and the upper surface of the second electrode part.

Furthermore, the dielectric constant of the first voltage-resistant dielectric layer and the dielectric constant of the second voltage-resistant dielectric layer are both greater than the dielectric constant of the interlayer dielectric layer.

Furthermore, the method of forming the first voltage-resistant dielectric layer includes forming a layer of voltage-resistant dielectric structure that covers the top surface of the interlayer dielectric layer, where the first voltage-resistant dielectric layer and the second voltage-resistant dielectric layer are made of the same material.

Furthermore, the method of forming the first voltage-resistant dielectric layer includes: forming a lower voltage-resistant dielectric layer that covers the top surface of the interlayer dielectric layer, forming an upper voltage-resistant dielectric layer on the lower voltage-resistant dielectric layer, and then etching the upper voltage-resistant dielectric layer so that it remains only on the lower surface of the second electrode part after forming the second electrode part.

Furthermore, the second voltage-resistant dielectric layer is disposed on both the lower voltage-resistant dielectric layer and the second electrode part to cover the side and upper surfaces of the second electrode part, as well as the side surfaces of the upper voltage-resistant dielectric layer.

Furthermore, the first voltage-resistant dielectric layer and the second voltage-resistant dielectric layer are made of silicon oxynitride (SiON) or silicon nitride (SiN) material.

Furthermore, the upper voltage-resistant dielectric layer is made of either SiON or SiN material, while the lower voltage-resistant dielectric layer is made of the other of the two materials.

Furthermore, the second voltage-resistant dielectric layer and the lower voltage-resistant dielectric layer are made of the same material.

Furthermore, it further includes providing a third voltage-resistant dielectric layer sandwiched between each pair of adjacent interlayer dielectric layers when multiple interlayer dielectric layers are provided.

Furthermore, it further includes patterning the second voltage-resistant dielectric layer on the second electrode part to create an opening that exposes a portion of the upper surface of the second electrode part.

The second embodiment of the present disclosure relates to a high-voltage capacitor, including a first electrode part, at least one interlayer dielectric layer disposed on the first electrode part and arranged in a stacked manner, a groove disposed in the top surface of the interlayer dielectric layer at a position overlapping with the first electrode part in a vertical direction, which extends from the top surface of the interlayer dielectric layer into its interior, and a second electrode part of the high-voltage capacitor disposed on the top surface of the interlayer dielectric layer, which overlaps with the groove and extends beyond the sides of the groove.

Furthermore, the width of the groove is smaller than the width of the second electrode part in a transverse direction, which is perpendicular to the vertical direction.

Furthermore, the depth of the groove ranges from 0.5 um to 3 um.

Furthermore, it further includes a first voltage-resistant dielectric layer disposed between the top surface of the interlayer dielectric layer and the second electrode part.

Furthermore, it further includes a second voltage-resistant dielectric layer disposed on the first voltage-resistant dielectric layer and the second electrode part, which covers the side surfaces and a portion of the upper surface of the second electrode part.

Furthermore, the dielectric constant of the first voltage-resistant dielectric layer and the dielectric constant of the second voltage-resistant dielectric layer are both greater than the dielectric constant of the interlayer dielectric layer.

Furthermore, the first voltage-resistant dielectric layer and the second voltage-resistant dielectric layer are made of the same material.

Furthermore, the first voltage-resistant dielectric layer includes a lower voltage-resistant dielectric layer and an upper voltage-resistant dielectric layer. The second voltage-resistant dielectric layer is made of the same material as the lower voltage-resistant dielectric layer of the first voltage-resistant dielectric layer that is away from the lower surface of the second electrode part.

Furthermore, the first voltage-resistant dielectric layer and the second voltage-resistant dielectric layer are made of SiON or SiN material.

Furthermore, the lower voltage-resistant dielectric layer of the first voltage-resistant dielectric layer is made of either SiON or SiN material, while the upper voltage-resistant dielectric layer is made of the other of the two materials.

Furthermore, the lower voltage-resistant dielectric layer of the first voltage-resistant dielectric layer covers the entire top surface of the interlayer dielectric layer, and the upper voltage-resistant dielectric layer of the first voltage-resistant dielectric layer is disposed only on the lower surface of the second electrode part.

Furthermore, the total thickness of the interlayer dielectric layer and first voltage-resistant dielectric layer between the upper surface of the first electrode part and the lower surface of the second electrode part is set to be greater than or equal to 10 um and less than or equal to 20 um.

Furthermore, when multiple interlayer dielectric layers are provided, a third voltage-resistant dielectric layer is disposed between two of the adjacent interlayer dielectric layers.

The third embodiment of the present disclosure relates to an integrated device, including a substrate with a first region and a second region, where a semiconductor device is located in the second region, the above-mentioned high-voltage capacitor located above the first region, a metal layer and a conductive via located in each interlayer dielectric layer and above the second region, where the metal layer and the conductive via lead out the corresponding electrodes of the semiconductor device. The first electrode part is formed simultaneously with the metal layer located in the same interlayer dielectric layer, while the second electrode part is formed simultaneously with the metal layer located in the same interlayer dielectric layer.

According to the application, a groove is arranged in the top surface of the interlayer dielectric layer, the thickness of the interlayer dielectric layer between the first electrode part and the edge of the lower surface of the second electrode part is increased compared to the middle part. This reduces the electric field distribution at the corners of the second electrode part and improves the withstand voltage performance of the high-voltage capacitor.

The present disclosure improves the voltage resistance of the capacitor by disposing a first voltage-resistant dielectric layer under the second electrode part of the high-voltage capacitor, where the dielectric constant of the first voltage-resistant dielectric layer is greater than that of the interlayer dielectric layer, and the first voltage-resistant dielectric layer is arranged into two layers, further increasing the thickness of the dielectric layer and enhancing the voltage resistance of the capacitor. In addition, a second voltage-resistant dielectric layer is provided on the upper and side surfaces of the second electrode part of the capacitor to cover the corners of the second electrode part, so as to reduce electric field concentration at the corners of the second electrode part. Furthermore, the second voltage-resistant dielectric layer is made of the same material as that of the first voltage-resistant dielectric layer or the lower voltage-resistant dielectric layer to avoid delamination of the dielectric layer and improve the performance of the device.

### BRIEF DESCRIPTION OF DRAWINGS

The above and other objects, features, and advantages of the present disclosure will be clearer by referring to the accompanying drawings for the following detailed description of the embodiments of the present disclosure, in which:

FIG. 1 is a cross-sectional structural diagram of a high-voltage capacitor according to Embodiment 1 of the present disclosure;

FIG. 2 is a cross-sectional structural diagram of a high-voltage capacitor according to Embodiment 2 of the present disclosure;

FIG. 3 is a cross-sectional structural diagram of a high-voltage capacitor according to Embodiment 3 of the present disclosure;

FIG. 4 is a cross-sectional structural diagram of a high-voltage capacitor according to Embodiment 4 of the present disclosure; and

FIGS. 5A-5D are cross-sectional diagrams of intermediate structures after certain steps following the method for forming the high-voltage capacitor according to one embodiment of the present disclosure.

### DETAILED DESCRIPTION

The following describes the present disclosure based on the embodiments, but the present invention is not merely limited to these embodiments. The detailed descriptions of the present disclosure in the following elaborate on some specific details. Those skilled in the art can fully understand the present disclosure without the description of these details. Well-known methods, procedures, processes, components and circuits are not described in detail to avoid obscuring the essence of the present disclosure.

In addition, the person skilled in the art should understand that the accompanying drawings are only for the purpose of illustration and are not drawn to scale.

Unless otherwise specified and limited, terms such as “installation”, “connection”, “fixing”, “fastening” should be broadly understood, for example, it can be a fixed connection, a detachable connection, or a monolithic connection; it can be a mechanical connection, or an electrical connection; it can be a direct connection, or an indirect connection through an intermediate medium, and it also can be an internal connection between two components. For those skilled in art, the specific meanings of the above terms in the context can be understood according to the specific situation.

Terms related to space, such as “inside”, “outside”, “below”, “under”, “lower”, “above”, and “upper”, can be used in the text to illustrate the relationship between one component or feature and another component or feature shown in the drawings. It should be understood that spatially related terms may also encompass orientations different from those depicted in the drawings, including those that occur during the use or operation of the device. For example, if the device in the drawing is flipped, an element described as being “below” or “underneath” another element or feature would then be positioned above that other element or feature. Thus, the term “below” in the example can encompass both orientations of above and below. The device may be oriented differently (e.g., rotated 90 degrees or positioned in other orientations), and the spatially related terms used here should be interpreted accordingly.

Unless otherwise required by the context, the terms “comprise” or “comprising,” “include” or “including” and the like used in the whole description herein and throughout the claims should be interpreted as inclusive meaning rather than exclusive or exhaustive meaning. In other words, the terms “comprise” or “comprising,” “include” or “including” and the like used in the whole description herein and throughout the claims should be interpreted as meaning of “including but be not limited to.”

In the description of the present disclosure, it should be understood that the terms “first”, “second” and the like are only used for the purpose of explanation and should not be construed as indicating or implying relative importance. Additionally, in the description of the present disclosure, “plural” means two or more unless otherwise specified.

In the description of the present disclosure, it should be noted that the embodiments and features of the embodiments in the present disclosure can be combined with each other as long as there is no conflict.

The technical solution of the present disclosure will be further described below with reference to the accompanying drawings and specific embodiments.

FIG. 1 is a cross-sectional structural diagram of a high-voltage capacitor according to Embodiment 1 of the present disclosure. The structure has at least one interlayer dielectric layer. The capacitor includes a first electrode part; at least one interlayer dielectric layer disposed on the first electrode part; a groove disposed in a top surface of the interlayer dielectric layer, wherein projection of the groove in a vertical direction overlaps with the first electrode part; and a second electrode part of the high-voltage capacitor configured to cover the groove and part of the top surface of the interlayer dielectric layer connected with both sides of the groove. In some embodiments, the structure has a stack of interlayer dielectric layers. The high-voltage capacitor is arranged to be in the first region of the stack of interlayer dielectric layers. The high-voltage capacitor includes first electrode part 101, second electrode part 102, and a dielectric medium which is a portion of the stack of the interlayer dielectric layers sandwiched between first electrode part 101 and second electrode part 102. The dielectric medium includes top interlayer dielectric layer IMD4 partly under second electrode part 102. Groove 103 is disposed in top interlayer dielectric layer IMD4 under second electrode part 102, where the vertical projection of groove 103 overlaps with first electrode part 101. The width d1 of groove 103 is smaller than the width d2 of second electrode part 102 in a transverse direction, which is perpendicular to the vertical direction. The thickness of second electrode part 102 is greater than the depth of groove 103, and the depth of groove 103 is set to range from 0.5 um to 3 um. The width of first electrode part 101 is greater than the width of groove 103.

In this embodiment, it further includes first dielectric layer 105 disposed on top interlayer dielectric layer IMD4 and second electrode part 102, covering the side surfaces and a portion of the upper surface of second electrode part 102. First dielectric layer 105 may include opening 115 to expose a portion of the upper surface of second electrode part 102. The material of first dielectric layer 105 may be the same as the material of the interlayer dielectric layers, or may be different, and is not limited here.

As the electric field concentrates at sharp corners or edges, breakdown may early occur at these points, which reduces voltage withstanding capability of the device. The present disclosure can reduce the electric field concentration at the edges and corners of second electrode part 102 by providing groove 103 underneath second electrode part 102 in top interlayer dielectric layer IMD4, so a thickness of the dielectric layer between edges of a lower surface of second electrode part 102 and first electrode part 101 is greater than a thickness of the dielectric layer between other positions of the lower surface of second electrode part 102 and first electrode part 101, thereby the capacitor's voltage breakdown is increased.

In this embodiment, the dielectric medium includes three interlayer layers IMD2, IMD3 and IMD4. That is, second interlayer dielectric layer IMD2, third interlayer dielectric layer IMD3, and fourth interlayer dielectric layer IMD4 are sandwiched between first electrode part 101 and second electrode part 102 of the capacitor. Second interlayer dielectric layer IMD2 is configured to cover an upper surface and the side surfaces of first electrode part 101. First electrode part 101 of the capacitor is disposed on substrate 100. The total thickness of the dielectric medium provided between the upper surface of first electrode part 101 and the lower surface of second electrode part 102 is greater than or equal to 5 um and less than or equal to 25 um. Of course, in other embodiments, the dielectric medium between first electrode part 101 and second electrode part 102 of the capacitor may include other layers, that is, it may include other interlayer dielectric layers between any adjacent layers. The number of interlayer dielectric layers in the stack included is not limited and can be determined based on the required voltage withstand of the capacitor.

It should be noted that the high-voltage capacitor is generally integrated onto a semiconductor die, which includes a semiconductor substrate with active devices, such as metal oxide semiconductor transistor devices, where there are a high-voltage capacitor region and an active region on the semiconductor substrate, and the active region includes metal layers (131, 132, 133, 134) and conductive vias (141, 142, 143) that lead out electrodes of the active devices. The conductive vias electrically connect two adjacent metal layers. Each interlayer dielectric layer includes a metal layer and at least one conductive via. In this embodiment, bottom metal layer 131 is located on the same layer as first electrode part 101 of the high-voltage capacitor, and top metal layer 134 is located on the same layer as second electrode part 102 of the high-voltage capacitor.

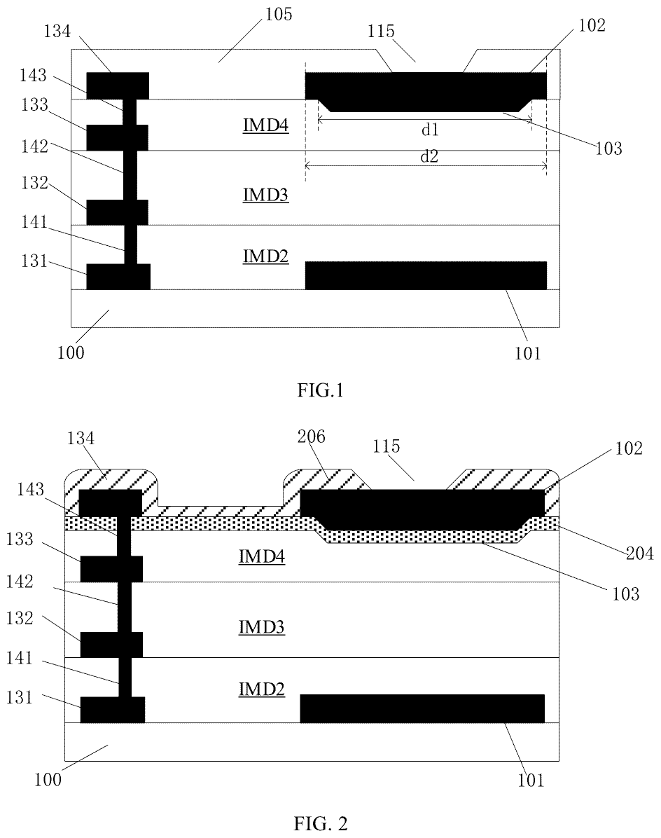

FIG. 2 is a cross-sectional structural diagram of a high-voltage capacitor according to Embodiment 2 of the present disclosure. The structure includes a stack of interlayer dielectric layers and a first voltage-resistant dielectric layer on the stack. The high-voltage capacitor is arranged to be in one region of the structure. The high-voltage capacitor includes first electrode part 101, second electrode part 102, and a dielectric medium which includes a portion of the stack of interlayer dielectric layers and the first voltage-resistant dielectric layer is sandwiched between first electrode part 101 and second electrode part 102. Groove 103 (similar to FIG. 1) is disposed in top interlayer dielectric layer IMD4, wherein the vertical projection of groove 103 overlaps with first electrode part 101. First voltage-resistant dielectric layer 204 is disposed to cover top surface of interlayer dielectric layer IMD4 including groove 103. The second electrode part 102 of the high-voltage capacitor disposed on part of first voltage-resistant dielectric layer 204 in groove 103. The structure also includes second voltage-resistant dielectric layer 206, disposed on first voltage-resistant dielectric layer 204, the side surfaces and the upper surface of second electrode part 102, wherein there is opening 115 in second voltage-resistant dielectric layer 206 exposing part of second electrode part 102. The width of groove 103 is smaller than width of second electrode part 102 in the transverse direction, which is perpendicular to the vertical direction. The thickness of second electrode part 102 is greater than the depth of groove 103. The depth of groove 103 ranges from 1 um to 3 um.

The dielectric constant of first voltage-resistant dielectric layer 204 and the dielectric constant of second voltage-resistant dielectric layer 206 are both greater than the dielectric constant of the interlayer dielectric layers. The positions of first electrode part 101 and second electrode part 102 correspond to each other in a vertical direction. In this embodiment, first electrode part 101 is provided as a lower electrode plate of the capacitor and second electrode part 102 is provided as an upper electrode plate of the capacitor. Opening 115 of second voltage-resistant dielectric layer 206 is used for electrical connection to an external circuit.

In this embodiment, there is only one voltage-resistant dielectric layer 204 on the upper surface of the top interlayer dielectric layer IMD4. The one layer of voltage-resistant dielectric structure 204 can be made from SiN or SiON material. Preferably, the second voltage-resistant dielectric layer 206 is made of the same material as voltage-resistant dielectric structure 204, so they offer better enclosure to the second electrode part. The thickness of second voltage-resistant dielectric layer 206 is set to a range of 1 um-4 um, and the thickness of the first voltage-resistant dielectric layer 204 is set to a range of 0.5 um-3 um.

Conductive via 143 starts from metal layer 133 and sequentially passes through interlayer dielectric layer IMD4 and first voltage-resistant dielectric layer 204, to metal layer 134.

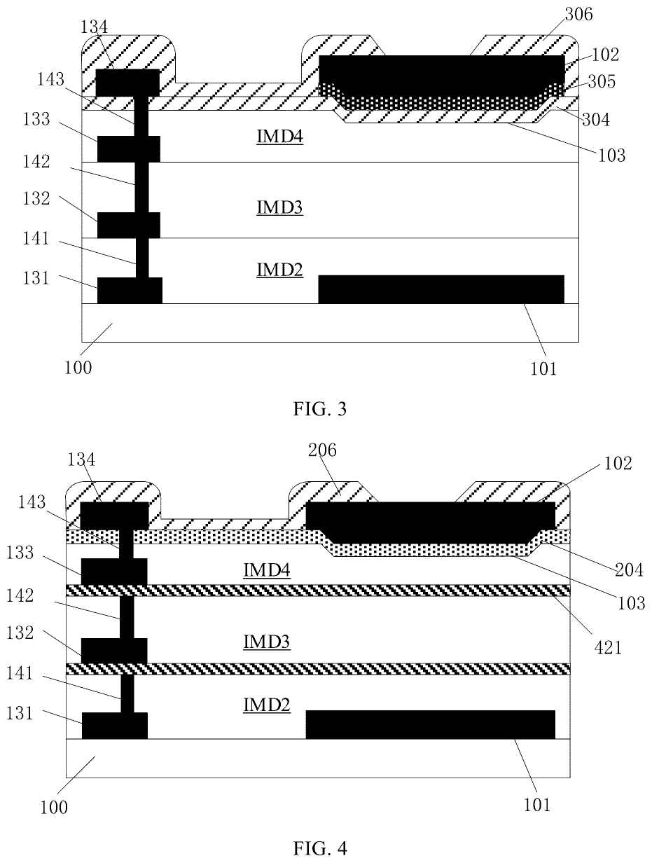

In other embodiments, as shown in FIG. 3, the first voltage-resistant dielectric layer includes two sub layers, one lower voltage-resistant dielectric sub-layer 304 and one upper voltage-resistant dielectric sub-layer 305. The lower voltage-resistant dielectric sub-layer 304 is disposed on the top interlayer dielectric layer IMD4 that includes the groove, and the upper voltage-resistant dielectric sub-layer 305 is disposed only beneath the lower surface of the second electrode part 102. The second voltage-resistant dielectric layer 306 is disposed on both the lower voltage-resistant dielectric layer sub-304 and the second electrode part 102, to cover the side surfaces of both the second electrode part 102 and the upper voltage-resistant dielectric sub-layer 305. The upper voltage-resistant dielectric sub-layer 305 and the lower voltage-resistant dielectric sub-layer 304 are made of different materials. The upper voltage-resistant dielectric sub-layer 305 is selected from either SiN material or SiON material, and the lower voltage-resistant dielectric sub-layer 304 is selected from the other of the two materials. The second voltage-resistant dielectric layer 306 is made of the same material as one of the upper voltage-resistant dielectric sub-layer 305 and the lower voltage-resistant dielectric sub-layer 304. Preferably, the second voltage-resistant dielectric layer 306 is made of the same material as the lower voltage-resistant dielectric layer sub-304. This can more effectively enclose the second electrode part 102, preventing delamination that could negatively impact the capacitor's voltage resistance performance. In addition, the thickness of the second voltage-resistant dielectric layer is set to be in the range of 1 um to 4 um, and the thickness of the first voltage-resistant dielectric layer is set to be in the range of 0.5 um to 3 um.

FIG. 4 is a cross-sectional structural diagram of a high-voltage capacitor according to Embodiment 4 of the present disclosure. The difference here from the high-voltage capacitor according to Embodiment 2 is that the stack of interlayer dielectric layers further includes a third voltage-resistant dielectric layer disposed between two adjacent interlayer dielectric layers. The rest of the structure remains the same as that in Embodiment 2 and will not be described again.

Specifically, the high-voltage capacitor further includes third voltage-resistant dielectric layer 421 disposed between two adjacent layers in the stack of interlayer dielectric layers sandwiched between first electrode part 101 and second electrode part 102, where third voltage-resistant dielectric layer 421 may be selected from one of SiN material and SiON material.

Furthermore, in the active region of the semiconductor die, third voltage-resistant dielectric layer 421 is disposed below and in contact with each metal layer.

The third voltage-resistant dielectric layer is provided between two adjacent interlayer dielectric layers so as to further increase the voltage resistance of the high-voltage capacitor.

The present invention also provides a manufacturing method for a high-voltage capacitor including: forming a first electrode part of the high-voltage capacitor; forming a stack of at least one interlayer dielectric layers on the first electrode part; forming a groove in the top interlayer dielectric layer at a position overlapping with the first electrode part in a vertical direction; forming a second electrode part of the high-voltage capacitor on top interlayer dielectric layer of the stack of interlayer dielectric layers, where the second electrode part conformally covers the groove and a portion of the upper surface of the top interlayer dielectric layer. The width of the groove is smaller than the width of the second electrode part in a transverse direction, where the transverse direction is perpendicular to the vertical direction.

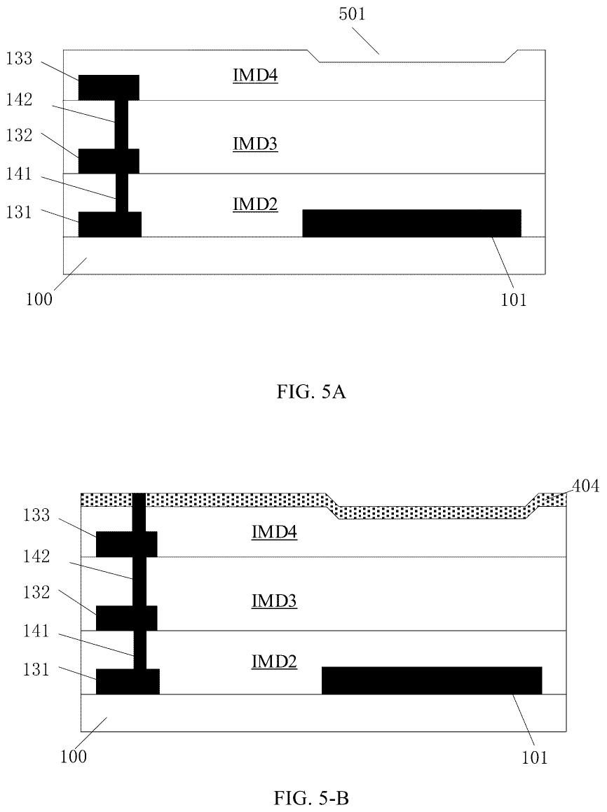

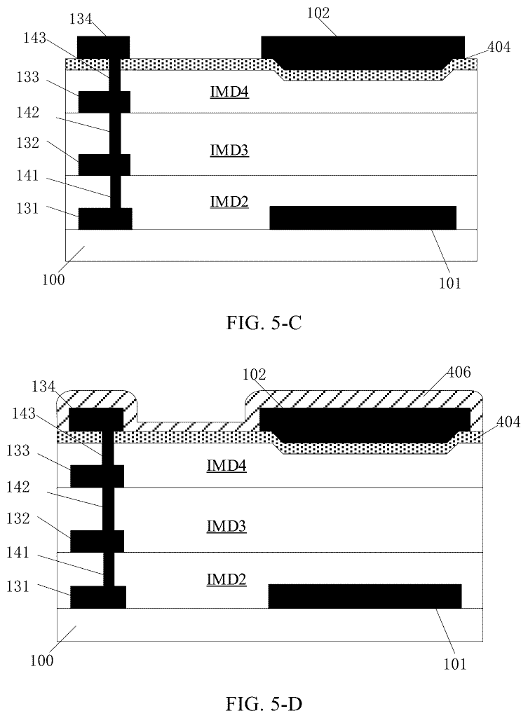

Specifically, as shown in FIG. 5A, providing a substrate 100 which includes an active region and a capacitor region, forming first electrode part 101 of the high-voltage capacitor in the capacitor region on the substrate 100, forming a stack of interlayer dielectric layers (IMD2, IMD3, IMD4) on first electrode part 101, and then forming groove 501 on the upper surface of the top interlayer dielectric layer IMD4. A stack of interlayer dielectric layers can include at least layer interlayer dielectric layer. In other embodiments, forming one-layer interlayer dielectric layer on first electrode part 101 can be also provided.

Groove 501 is formed on the top surface of the interlayer dielectric layer IMD4 using an etching process. The etching process is preferably a dry etching process. The projection of groove 501 overlaps with the projection of the first electrode part in a vertical direction. The width of the groove is smaller than the width of the second electrode part in a transverse direction, where the transverse direction is perpendicular to the vertical direction. The depth range of the groove is set to 0.5 um to 3 um.

In this embodiment, the stack of interlayer dielectric layers includes second interlayer dielectric layer IMD2, third interlayer dielectric layer IMD3, and fourth interlayer dielectric layer IMD4. First electrode part 101 of the high-voltage capacitor is formed on the substrate 100, then the stack of interlayer dielectric layers are sequentially deposited on the substrate 100 and first electrode part 101. The process is commonly used in the industry to form the interlayer dielectric layers, and will not be repeated here.

It should be noted that the high-voltage capacitor is generally integrated onto a semiconductor die, which includes a semiconductor substrate with active devices, such as metal oxide semiconductor transistor devices, where the semiconductor substrate includes a high-voltage capacitor region and an active region, and the active region includes metal layers (131, 132, 133) and conductive vias (141, 142) that lead out electrodes of the active devices. The conductive vias electrically connect two adjacent metal layers. Each interlayer dielectric layer includes a metal layer and at least one conductive via. In this embodiment, the metal layer 131 is located on the same layer as first electrode part 101 of the high-voltage capacitor.

In other embodiments, the method further includes forming third voltage-resistant dielectric layer 421 between adjacent two interlayer dielectric layers of the stack of interlayer dielectric layers. In the active region, third voltage-resistant dielectric layer 421 is disposed below each metal layer, as shown in FIG. 4.

As shown in FIG. 5B, forming a first voltage-resistant dielectric layer on top interlayer dielectric layer of the stack of the interlayer dielectric layers.

The method of forming the first voltage-resistant dielectric layer includes: forming one layer of dielectric layer structure 404 on the stack of interlayer dielectric layers, and the one layer of dielectric layer structure 404 is made of a SiN material or a SiON material. The first voltage-resistant dielectric layer covers the upper surface of the top interlayer dielectric layer that includes the groove in the capacitor region.

Furthermore, in other embodiments, as shown in FIG. 3, the method of forming the first voltage-resistant dielectric layer includes: forming lower voltage-resistant dielectric sub-layer 304 on the upper surface of the top interlayer dielectric layer that includes the groove, and forming upper voltage-resistant dielectric sub-layer 305 on lower voltage-resistant dielectric sub-layer 304. The lower voltage-resistant dielectric sub-layer 304 and the upper voltage-resistant dielectric sub-layer 305 are formed through deposition process. The deposition process includes a physical vapor deposition process (PVD), a chemical vapor deposition process (CVD), an atomic layer deposition process (ALD) and the like.

Upper voltage-resistant dielectric sub-layer 305 is selected from either SiN material or SiON material, and lower voltage-resistant dielectric sub-layer 304 is selected from the other of SiN material or SiON material. The thickness of the SiN material ranges from 0.5 um to 2 um, while the thickness of the SiON material ranges from 0.5 um to 1 um.

In addition, it also includes forming a via in the first voltage-resistant dielectric layer and the top interlayer dielectric layer (the fourth interlayer dielectric layer IMD4), and depositing conductive material in the via to form conductive via 143 in the active region.

It should be noted that in alternative embodiments, the steps shown in FIG. 5B can also be omitted. Second electrode part 102 of the high-voltage capacitor can be formed directly on top interlayer dielectric layer IMD4, and then forming first dielectric layer 105 covering top interlayer dielectric layer IMD4 as well as the side surfaces and a portion of the upper surfaces of second electrode part 102, as shown in FIG. 1.

As shown in FIG. 5C, forming second electrode part 102 of the high-voltage capacitor on first voltage-resistant dielectric layer 404, specifically, first depositing a metal layer on first voltage-resistant dielectric layer 404, the metal layer covers the upper surface of first voltage-resistant dielectric layer 404, and then etching part of the metal layer until reaching the upper surface of the first voltage-resistant dielectric layer. It should be noted that when the first voltage-resistant dielectric layer includes both an upper voltage-resistant dielectric sub-layer and a lower voltage-resistant dielectric sub-layer, etching part of the metal layer and part of the upper voltage-resistant dielectric layer simultaneously until reaching the upper surface of the lower voltage-resistant dielectric layer, the part of the upper voltage-resistant dielectric layer that needs to be removed to be completely etched away by controlling over-etching.

The method of etching part of the metal layer includes: forming a patterned photoresist layer on the metal layer, where the photoresist layer covers the portion of the metal layer that overlaps with the first electrode part in the vertical direction; then etching the exposed metal layer using the photoresist layer as a mask to form second electrode part 102.

Furthermore, the photoresist layer also covers the portion of the metal layer that overlaps with the interlayer metal layer (131, 132, 133) in the vertical direction. After the etching process, this portion of the metal layer is retained as interlayer metal layer 134.

As shown in FIG. 5D, forming a second voltage-resistant dielectric layer that surrounds the side surfaces and upper surface of second electrode part 102 and the upper surface of first voltage-resistant dielectric layer.

Specifically, in this embodiment, depositing second voltage-resistant dielectric layer 406 on second electrode part 102 and first voltage-resistant dielectric layer 404, where second voltage-resistant dielectric layer 406 covers the upper surface of first voltage-resistant dielectric layer 404, as well as the upper surface and the side surfaces of second electrode part 102 (and interlayer metal layer 134).

In the embodiment shown in FIG. 3, the first voltage-resistant dielectric layer includes an upper voltage-resistant dielectric layer and a lower voltage-resistant dielectric layer. Second voltage-resistant dielectric layer 306 covers the upper surface of lower voltage-resistant dielectric sub-layer 304, the upper surface and side surfaces of second electrode part 102 (and interlayer metal layer 134), and the side surface of upper voltage-resistant dielectric sub-layer 305.

As shown in FIG. 2, the method further includes forming an opening 115 in the second voltage-resistant dielectric layer to expose a portion of the upper surface of second electrode part 102. Furthermore, a welding structure is formed on the exposed upper surface of the second electrode part to realize an electrical connection with an external circuit.

The preferred embodiments of the present disclosure are discussed above but is not used to limit the present disclosure. The person skilled in the art can make various amendments or modification to the present disclosure. Any modification, equivalent replacement, improvement, etc. made within the spirit and principle of the present disclosure shall be within the protection scope of the present disclosure.

1. A method of manufacturing for a high-voltage capacitor, comprising:
providing a substrate, forming a first electrode part of the high-voltage capacitor on the substrate;
forming at least one interlayer dielectric layer on the substrate, wherein the interlayer dielectric layer is disposed on the first electrode part;
forming a groove in a top surface of the interlayer dielectric layer, wherein projection of the groove in a vertical direction overlaps with the first electrode part; and
forming a second electrode part of the high-voltage capacitor on the top surface of the interlayer dielectric layer, wherein the second electrode part covers the groove and part of the top surface of the interlayer dielectric layer connected with both sides of the groove.

2. The method according to claim 1, wherein a width of the groove is smaller than a width of the second electrode part in a transverse direction, the transverse direction is perpendicular to the vertical direction.

3. The method according to claim 1, wherein after forming the groove, a first voltage-resistant dielectric layer is formed on the groove and the top surface of the interlayer dielectric layer, wherein the second electrode part is disposed on an upper surface of the first voltage-resistant dielectric layer.

4. The method according to claim 3, further comprising forming a second voltage-resistant dielectric layer on the top surface of the interlayer dielectric layer and the second electrode part, wherein the second voltage-resistant dielectric layer covers side surfaces and an upper surface of the second electrode part.

5. The method according to claim 4, wherein a dielectric constant of the first voltage-resistant dielectric layer and a dielectric constant of the second voltage-resistant dielectric layer are both greater than a dielectric constant of the interlayer dielectric layer.

6. The method according to claim 4, wherein the forming of the first voltage-resistant dielectric layer comprises: forming one layer of voltage-resistant dielectric structure that covers the top surface of the interlayer dielectric layer, wherein the first voltage-resistant dielectric layer and the second voltage-resistant dielectric layer are made of a same material.

7. The method according to claim 4, wherein the forming of the first voltage-resistant dielectric layer comprises:
disposing a lower voltage-resistant dielectric sub-layer on the top surface of the interlayer dielectric layer;
disposing an upper voltage-resistant dielectric sub-layer on the lower voltage-resistant dielectric sub-layer; and
removing, after forming the second electrode part, a part of the upper voltage-resistant dielectric sub-layer not be covered by the second electrode part.

8. The method according to claim 7, wherein the second voltage-resistant dielectric layer is disposed on both the lower voltage-resistant dielectric sub-layer and the second electrode part, wherein the second voltage-resistant dielectric layer covers the side surfaces and the upper surface of the second electrode part, as well as side surfaces of an upper voltage-resistant dielectric sub-layer.

9. The method according to claim 1, further comprising: providing a third voltage-resistant dielectric layer sandwiched between two adjacent interlayer dielectric layers when multiple interlayer dielectric layers are provided.

10. A high-voltage capacitor, comprising:
a first electrode part;
at least one interlayer dielectric layer disposed on the first electrode part;
a groove disposed in a top surface of the interlayer dielectric layer, wherein projection of the groove in a vertical direction overlaps with the first electrode part; and
a second electrode part of the high-voltage capacitor configured to cover the groove and part of the top surface of the interlayer dielectric layer connected with both sides of the groove.

11. The high-voltage capacitor according to claim 10, wherein a width of the groove is smaller than a width of the second electrode part in a transverse direction, which is perpendicular to the vertical direction.

12. The high voltage capacitor according to claim 10, wherein a depth of the groove ranges from 1 um to 3 um.

13. The high-voltage capacitor according to claim 10, further comprising: a first voltage-resistant dielectric layer sandwiched between the top surface of the interlayer dielectric layer and the second electrode part.

14. The high-voltage capacitor according to claim 13, further comprising: a second voltage-resistant dielectric layer disposed on the first voltage-resistant dielectric layer and the second electrode part, wherein the second voltage-resistant dielectric layer covers side surfaces and a portion of upper surface of the second electrode part.

15. The high voltage capacitor according to claim 14, wherein a dielectric constant of the first voltage-resistant dielectric layer and a dielectric constant of the second voltage-resistant dielectric layer are both greater than a dielectric constant of the interlayer dielectric layer.

16. The high-voltage capacitor according to claim 14, wherein the first voltage-resistant dielectric layer and the second voltage-resistant dielectric layer are made of the same material.

17. The high-voltage capacitor according to claim 19, wherein the first voltage-resistant dielectric layer comprises a lower voltage-resistant dielectric sub-layer and an upper voltage-resistant dielectric sub-layer, wherein the second voltage-resistant dielectric layer is made of the same material as the lower voltage-resistant dielectric sub-layer that is away from the lower surface of the second electrode part.

18. The high-voltage capacitor according to claim 17, wherein the lower voltage-resistant dielectric sub-layer of the first voltage-resistant dielectric layer covers the entire top surface of the interlayer dielectric layer, and the upper voltage-resistant dielectric sub-layer of the first voltage-resistant dielectric layer is disposed only below the lower surface of the second electrode part.

19. The high-voltage capacitor according to claim 15, wherein, when multiple interlayer dielectric layers are provided, a third voltage-resistant dielectric layer is provided and sandwiched between adjacent two interlayer dielectric layers.

20. An integrated device, comprising:
a substrate with a first region and a second region, and the second region comprising a semiconductor device;
the high voltage capacitor according to claim 10 located above the first region; and
a metal layer and a conductive via located in each interlayer dielectric layer and above the second region;
wherein the metal layer and the conductive via lead out the corresponding electrodes of the semiconductor device, and the first electrode part is formed simultaneously with the metal layer located in the same interlayer dielectric layer, the second electrode part is formed simultaneously with the metal layer located in the same interlayer dielectric layer.
